(19) United States
(12) Patent Application Publication
(10) Pub. No.: US 2009/0072335 A1
(43) Pub. Date: Mar. 19, 2009

(54) Image sensor package

(75) Inventors: Yul-Kyo Chung, Yongin-si (KR); Sung Yi, Suwon-si (KR); Won-Kyu Jeung, Seoul (KR); Jung-Won Lee, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/232,384

(22) Filed: Sep. 16, 2008

(30) Foreign Application Priority Data
Sep. 18, 2007 (KR) 10-2007-0094913

(51) Int. Cl. H01L 31/00

(52) U.S. Cl. 257/431; 257/E31.001

(57) ABSTRACT

An image sensor package is provided. The image sensor package may include a semiconductor substrate, an image sensor stacked over an upper surface of the semiconductor substrate, a pad formed on a lower surface of the semiconductor substrate and electrically connected with the image sensor, and a passive component formed by a thin film process on a lower surface of the semiconductor substrate and electrically connected with the pad.

### CROSS-REFERENCE TO RELATED APPLICATIONS

This application claims the benefit of Korean Patent Application No. 10-2007-0094913 filed with the Korean Intellectual Property Office on Sep. 18, 2007, the disclosure of which is incorporated herein by reference in its entirety.

### BACKGROUND

1. Technical Field

The present invention relates to an image sensor package that includes passive components embedded in a semiconductor substrate.

2. Description of the Related Art

In current electronic products, especially portable electronic devices, etc., the variety of consumer demands is continuously increasing. In particular, the demands for multi-functionality, compact sizes, light weight, high speeds, low costs, increased portability, real time access to the wireless Internet, and sophisticated designs are goading developers, designers, and manufacturers alike to provide superior products.

Increased competition in providing such products have led to more frequent releases of newer models, exacerbating the burden on those involved. The demands related to mobile products, such as cell phones, PDA's, digital cameras, and laptops, in particular, are greater than ever, one result of which is that the electronic parts for these products are being modularized and integrated, to implement multi-functionality, compact sizes, light weight, and low costs, etc. For a conventional image sensor package having an electrically connected passive component, the passive component 101 may be coupled to the printed circuit board 100 with a particular distance from the image sensor package 10, as in the example shown in FIG. 1. This distance between the passive component 101 and the image sensor package 10 may result in increased noise and parasitic capacitance, which may degrade the performance of the product.

### SUMMARY

An aspect of the invention provides an image sensor package, in which the passive component is arranged in the semiconductor substrate, to reduce parasitic capacitance, as well as to provide a smaller size.

Another aspect of the invention provides an image sensor package that includes a semiconductor substrate, an image sensor stacked over an upper surface of the semiconductor substrate, a pad formed on a lower surface of the semiconductor substrate and electrically connected with the image sensor, and a passive component formed by a thin film process on a lower surface of the semiconductor substrate and electrically connected with the pad.

The passive component can be a resistor or a capacitor.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a cross sectional view of a printed circuit board to which an image sensor package is coupled on, according to the related art.

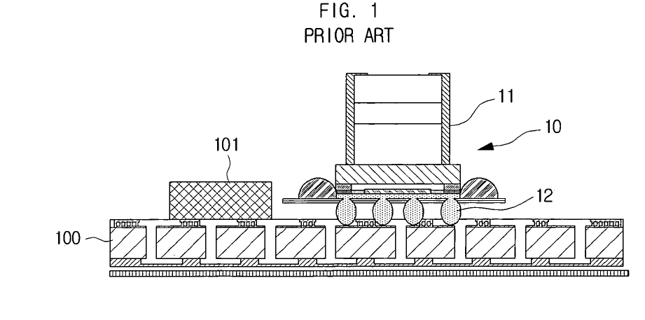

FIG. 2 is a cross sectional view of a printed circuit board to which an image sensor package is coupled on, according to an embodiment of the invention.

FIG. 3 is a cross sectional view of an image sensor package according to an embodiment of the invention.

FIG. 4 is a bottom view of an image sensor package according to an embodiment of the invention.

### DETAILED DESCRIPTION

The image sensor according to certain embodiments of the invention will be described below in more detail with reference to the accompanying drawings. Those elements that are the same or are in correspondence are rendered the same reference numeral regardless of the figure number, and redundant explanations are omitted.

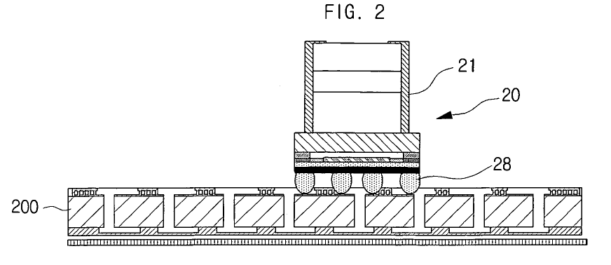

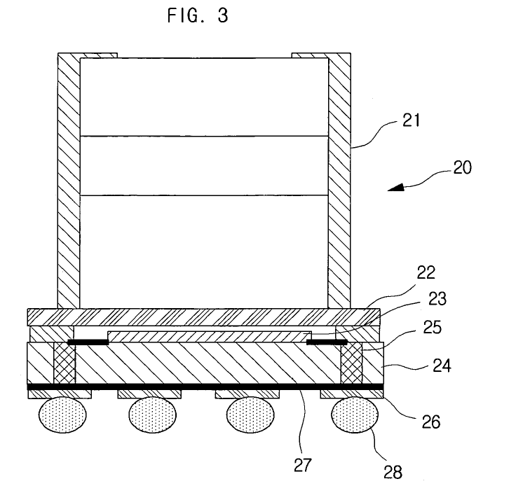

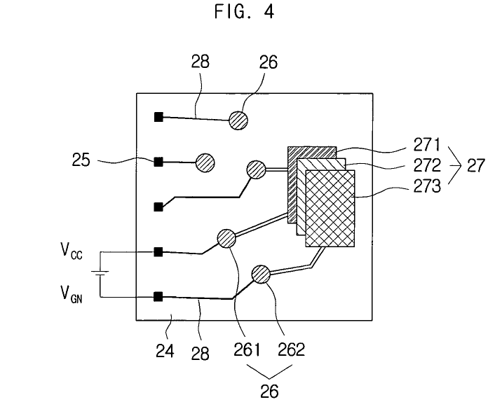

FIG. 2 is a cross sectional view of a printed circuit board, to which an image sensor package is coupled on, according to an embodiment of the invention. FIG. 3 is a cross sectional view of an image sensor package according to an embodiment of the invention, and FIG. 4 is a bottom view of an image sensor package according to an embodiment of the invention. In FIG. 2 through FIG. 4, there are illustrated an image sensor package 20, a lens assembly 21, glass 22, an image sensor 23, a semiconductor substrate 24, vias 25, pads 26, a capacitor 27, a lower electrode 271, a dielectric layer 272, an upper electrode 273, solder balls 28, and a printed circuit board 200.

As in the example shown in FIG. 2, the image sensor package 20 can be coupled to the printed circuit board 200 using solder balls 28.

Referring to FIG. 3, the structure of the image sensor package 20 can include an image sensor 23 formed on an upper surface of a semiconductor substrate 24, and a glass 22 coupled to an upper portion of the image sensor 23 to protect the image sensor 23. Also, to reduce external images, the lens assembly 21 can be positioned on an upper surface of the glass 22.

Pads 26 can be coupled on to a lower surface of the semiconductor substrate 24. As in the example shown in FIG. 3, pads 26 can be electrically connected with the image sensor 23. Pads 26 can also be electrically connected with a passive component, such as a capacitor 27. Not all of the pads 26 may be electrically connected with the capacitor 27, and just some may be connected with the capacitor 27. The pads 26 can be sufficiently wide to be coupled with the solder balls 28, and in certain embodiments, a surface treatment can be applied to the pads 26.

Vias 25 penetrating the semiconductor substrate 24 may be used to electrically connect the pads 26 with the image sensor 23.

One reason for positioning the image sensor 23 on one side and the capacitor 27 on the other side with the semiconductor substrate 24 in-between may be to efficiently utilize the limited area of the semiconductor substrate 24.

The semiconductor substrate 24 used in the image sensor package 20 is trending towards smaller sizes, to the wafer level. That is, there may not be any room on the upper surface of the semiconductor substrate 24 other than the area occupied by the image sensor 23. Thus, it can be advantageous to position the capacitor 27 on a lower surface of the semiconductor substrate 24.

By thus positioning the capacitor 27 on a lower surface of the semiconductor substrate 24, the electrical path from the image sensor 23 to the capacitor 27 can be shortened. As such, there may be considerably less noise and parasitic capacitance.

Whereas the above used a capacitor 27 as an example, other types of passive component, such as a resistor and a coil, can be formed as a thin film on the reverse side of the semiconductor substrate 24.

As shown in the bottom view of FIG. 4, the capacitor 27 can be formed by a thin film deposition process. Since a pad 26 may generally have a thickness of about 500 nm, and a capacitor may generally have a thickness of about 400 nm, it is very unlikely that the capacitor 27 will create an excessive protrusion on the reverse side of the semiconductor substrate 24. Thus, even when the image sensor package 20 is coupled to a printed circuit board 200 by attaching solder balls 28 onto the pads 26, the capacitor 27 may not obstruct the coupling.

As in the example shown in FIG. 4, circuit lines may connect the pads 26 with the vias 25, where the vias 25 may be electrically connected with the image sensor 23 of FIG. 3. Also, some of the pads 26 may be electrically connected with the capacitor 27.

As in the example shown in FIG. 4, the capacitor 27 can be composed of an upper electrode 273 and a lower electrode 271 on either side of a dielectric layer 272, where the upper electrode 273 and lower electrode 271 may be coupled respectively to the pads 262, 261. The pad 262 electrically connected with the upper electrode 273 can be electrically connected with the ground, while the pad 261 electrically connected with the lower electrode 271 can be electrically connected with a power supply terminal.

Whereas the above embodiments used a capacitor as an example, other types of passive component, such as a resistor, can be formed as a thin film on the reverse side of the semiconductor substrate.

According to certain embodiments of the invention as set forth above, in an image sensor that is being produced in smaller and smaller sizes to the wafer level, a passive component can be formed as a thin film on the reverse side of the semiconductor substrate, to allow an efficient use of space on the semiconductor substrate.

Also, by including the passive component in the package, the occurrence of noise or parasitic capacitance can be minimized, whereby the reliability of the image sensor package may be improved.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. An image sensor package comprising:
a semiconductor substrate;
an image sensor stacked on an upper surface of the semiconductor substrate;
a pad formed on a lower surface of the semiconductor substrate and electrically connected with the image sensor; and
a passive component formed by a thin film process on a lower surface of the semiconductor substrate and electrically connected with the pad.

2. The image sensor package of claim 1, wherein the passive component is a capacitor.

3. The image sensor package of claim 1, wherein the passive component is a resistor.
